(19) United States
(12) Patent Application Publication
(10) Pub. No.: US 2023/0262332 A1
(43) Pub. Date: Aug. 17, 2023

(54) SHAKE CORRECTION MECHANISM AND CAMERA MODULE INCLUDING SAME

(71) Applicant: Murata Manufacturing Co., Ltd., Nagaokakyo-shi (JP)

(72) Inventor: Daisuke NAKAMURA, Nagaokakyo-shi (JP)

(21) Appl. No.: 18/140,686

(22) Filed: Apr. 28, 2023

Related U.S. Application Data
(63) Continuation of application No. PCT/JP2021/036749, filed on Oct. 5, 2021.

(30) Foreign Application Priority Data
Dec. 9, 2020 (JP) 2020-203898

(51) Int. Cl. H04N 23/68; H10N 50/10

(52) U.S. Cl. CPC H04N 23/687; H04N 23/6812; H10N 50/10

(57) ABSTRACT

A periscope camera module includes a refractor to refract, in a direction of a second optical axis, incoming light that entered along a first optical axis, and a driver to rotate the refractor together with a holder around a first rotation axis and a second rotation axis. The driver includes a magnet and coils. The magnet is provided on the holder opposite to a side on which the incoming light enters the refractor in a direction of the first optical axis, and the coils face the magnet, and are provided on the same or substantially the same plane perpendicular or substantially perpendicular to the first optical axis.

### CROSS REFERENCE TO RELATED APPLICATIONS

This application claims the benefit of priority to Japanese Patent Application No. 2020-203898 filed on Dec. 9, 2020 and is a Continuation Application of PCT Application No. PCT/JP2021/036749 filed on Oct. 5, 2021. The entire contents of each application are hereby incorporated herein by reference.

### BACKGROUND OF THE INVENTION

### 1. Field of the Invention

The present disclosure relates to a shake correction mechanism including a refractor to refract a direction of an optical axis, and a camera module including the shake correction mechanism.

### 2. Description of the Related Art

In order to obtain high performance and make a difference with regard to a smartphone, a camera has to have high performance. In a high-performance compact camera module (CCM), an optical image stabilizer (OIS) mechanism is often mounted. In the OIS mechanism of the conventional CCM, generally, a lens module is moved in parallel in a direction perpendicular to an optical axis so as to change an image formation position of light.

When the number of lenses and a lens stroke are increased in order to increase an optical magnification in the conventional CCM, the thickness of the CCM is increased. As a result, a mobile terminal having the CCM mounted thereon cannot be thin. To address this, in recent years, attention has been directed to a periscope type CCM in which a refractor such as a prism is used to refract an optical path direction by 90°. In the periscope type CCM, a lens module is disposed at a position on the optical path refracted by the refractor, with the result that the optical magnification can be increased without increasing the thickness of the CCM.

Japanese Patent No. 6613005 describes a periscope type CCM in which an OIS mechanism can be realized by rotating a prism around two axes.

In the periscope type CCM described in Japanese Patent No. 6613005, the prism is rotated around two axes by voice coil motors disposed in a bottom surface direction and both side surface directions of the prism. Therefore, in the periscope type CCM described in Japanese Patent No. 6613005, it is necessary to provide coils and substrates for the coils in the bottom surface direction and both of the side surface directions of the prism. In the periscope type CCM described in Japanese Patent No. 6613005, it is necessary to further provide magnets corresponding to the coils on the bottom surface and both side surfaces of the prism. As a result, the periscope type CCM described in Japanese Patent No. 6613005 disadvantageously has a complicated configuration.

### SUMMARY OF THE INVENTION

Preferred embodiments of the present invention provide shake correction mechanisms with a simplified configuration.

A shake correction mechanism according to a preferred embodiment of the present invention includes a refractor to refract, in a direction of a second optical axis of an optical element system, incoming light that entered along a first optical axis, a holder to hold the refractor, and a driver to rotate the refractor together with the holder around a first rotation axis and a second rotation axis, the first rotation axis being parallel or substantially parallel to the first optical axis, the second rotation axis being perpendicular or substantially perpendicular to an imaginary plane defined by the first optical axis and the second optical axis. The driver includes a magnet and a plurality of coils. The magnet is provided on the holder at a position opposite to a side on which the incoming light enters the refractor in a direction of the first optical axis. The plurality of coils face the holder with the magnet interposed between each of the plurality of coils and the holder, and are disposed on a same or substantially a same plane perpendicular or substantially perpendicular to the first optical axis.

According to preferred embodiments of the present invention, since the plurality of coils are on the same or substantially the same plane, shake correction mechanisms each having a simplified configuration are obtained.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a transparent plan view of a periscope type compact camera module according to a first preferred embodiment of the present invention.

FIG. 2 is a transparent plan view of the periscope type compact camera module according to the first preferred embodiment of the present invention.

FIG. 3 is a perspective view of a prism for illustrating a relationship among a first optical axis, a second optical axis, a first rotation axis, and a second rotation axis.

FIG. 4 is a block diagram showing a configuration of the periscope type compact camera module according to a preferred embodiment of the present invention.

FIG. 5 is a diagram showing a relationship between a value of a current to be supplied to each of first to third coils and a rotation angle of the prism.

FIG. 6 is a graph showing a relationship between a rotation angle of the prism around the first rotation axis and an output voltage of a first rotation detection sensor.

FIG. 7 is a graph showing a relationship between a rotation angle of the prism around the second rotation axis and an output voltage of a second rotation detection sensor.

FIG. 8 is a flowchart showing a content of control for rotating the prism around the two axes according to the first preferred embodiment of the present invention.

FIG. 9 is a transparent plan view of a periscope type compact camera module according to a second preferred embodiment of the present invention.

FIG. 10 is a flowchart showing a content of control for rotating a prism around the two axes according to the second preferred embodiment of the present invention.

### DETAILED DESCRIPTION OF THE PREFERRED EMBODIMENTS

Hereinafter, preferred embodiments of the present invention will be described in detail with reference to drawings. In the drawings, the same or corresponding portions are denoted by the same reference characters and will not be described repeatedly.

### First Preferred Embodiment

### Explanation for Structure of Periscope Type Compact Camera Module 100

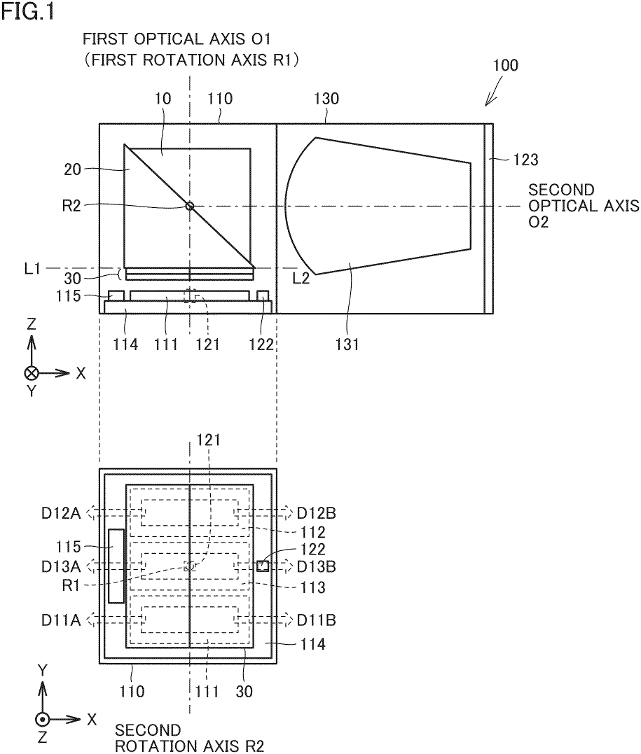

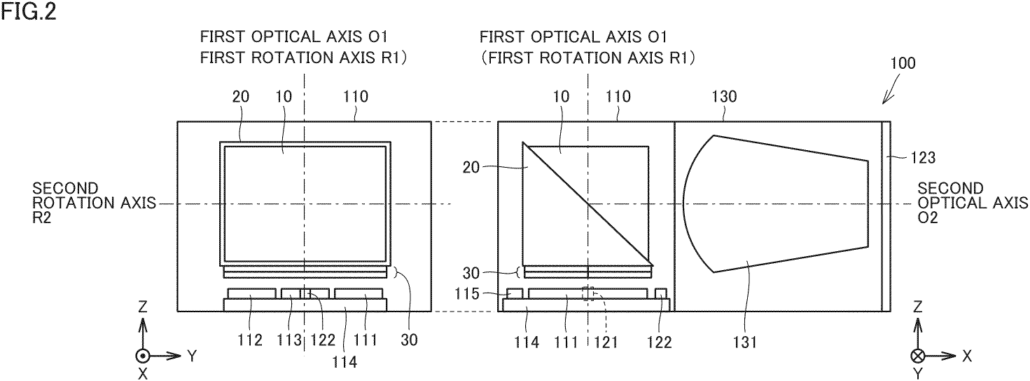

Each of FIGS. 1 and 2 is a transparent plan view of a-+ periscope type compact camera module 100 according to a first preferred embodiment of the present invention. In the description below, a positive direction on a Z axis may be referred to as an upper side and a negative direction on the Z axis may be referred to as a lower side in each of FIGS. 1 and 2.

In particular, the upper portion of FIG. 1 shows a diagram of periscope type compact camera module 100 when viewed in a Y axis direction. As shown in the upper portion of FIG. 1, periscope type compact camera module 100 includes a shake prevention mechanism (shake correction mechanism) 110 and an autofocus mechanism 130.

The lower portion of FIG. 1 shows a diagram of a lower side of shake prevention mechanism 110 below a line segment L1-L2 when viewed from the upper side thereof. A diagram on the right side of FIG. 2 is the same as the diagram on the upper portion of FIG. 1, and a diagram on the left side of FIG. 2 shows periscope type compact camera module 100 when viewed from the autofocus mechanism 130 side in an X axis direction.

Shake prevention mechanism 110 is provided with a prism 10 and a prism holder 20 that holds prism 10. Autofocus mechanism 130 is provided with an optical system lens group (optical element system) 131 that adjusts a magnification and a focal point, and an image sensor 123. Light coming from a subject and having entered periscope type compact camera module 100 enters prism 10 along a first optical axis O1 that is a light entrance axis. The light having entered prism 10 is refracted by a refracting surface of prism 10 and is then sent out therefrom.

The light sent out from the refracting surface of prism 10 travels along a second optical axis O2. Second optical axis O2 defines an optical axis of optical system lens group 131. The light having traveled through optical system lens group 131 along second optical axis O2 provides an image of the subject on an imaging surface of image sensor 123.

Prism holder 20 holds prism 10 to be rotatable around two axes, i.e., a first rotation axis R1 along the Z axis and a second rotation axis R2 along the Y axis. Various configurations are conceivable for a configuration of prism holder 20 to hold prism 10 to be rotatable around the two axes.

For example, in the configuration shown on the left side of FIG. 2, it is conceivable to configure prism holder 20 to float in air by providing magnets on both side surfaces of prism holder 20 in the Y axis direction and by providing magnets on both side surfaces of shake prevention mechanism 110 so as to face the above-described magnets to obtain repulsive forces with regard to the magnets on the side surface sides of prism holder 20.

First rotation axis R1 is an axis along first optical axis O1. Second rotation axis R2 is an axis along a direction orthogonal or substantially orthogonal to an imaginary plane defined by first optical axis O1 and second optical axis O2. Preferably, first rotation axis R1 coincides with first optical axis 01, and second rotation axis R2 coincides with an axis extending, in the Y axis direction, through a position of prism 10 at which first optical axis O1 and second optical axis O2 intersect each other.

A magnet 30, which defines a portion of a voice coil motor, is fixed to a bottom surface of prism holder 20. A position at which magnet 30 is provided corresponds to a position opposite in the direction of first optical axis O1 to a side on which the incoming light enters. The polarity of magnet 30 is divided into an N pole and an S pole along second rotation axis R2 shown in the diagram on the lower portion of FIG. 1. In the present preferred embodiment, a quadrupole magnet having, for example, a two-layer structure is used as magnet 30.

A first layer of the two layers, i.e., a layer close to the prism holder 20 side, includes a side that corresponds to the N pole and that is close to autofocus mechanism 130 in the X axis direction, and includes a side that corresponds to the S pole and that is spaced away from autofocus mechanism 130 in the X axis direction. In contrast, a second layer thereof includes a side that corresponds to the S pole and that is close to autofocus mechanism 130 in the X axis direction, and includes a side that corresponds to the N pole and that is spaced away from autofocus mechanism 130 in the X axis direction.

A substrate 114 is attached to the bottom surface of shake prevention mechanism 110. Substrate 114 is provided with a plurality of coils that are combined with magnet 30 to define a voice coil motor. In the present preferred embodiment, a first coil 111, a second coil 112, and a third coil 113, which are an example of the plurality of coils, are attached to substrate 114. First coil 111, second coil 112, and third coil 113 are coils having the same or substantially the same size.

First coil 111 and second coil 112 are located beside both sides of third coil 113. First coil 111, second coil 112, and third coil 113 are provided on substrate 114 at equal or substantially equal intervals along the direction of second rotation axis R2. The side surfaces of first coil 111, second coil 112, and third coil 113 in the X axis direction are parallel or substantially parallel to the X axis direction. The side surfaces of first coil 111, second coil 112, and third coil 113 in the Y axis direction are parallel or substantially parallel to the Y axis direction.

First coil 111, second coil 112, and third coil 113 are disposed side by side on the same plane in a direction orthogonal or substantially orthogonal to a direction (X axis direction) passing through the N pole and S pole of magnet 30 located thereabove in relation to magnet 30. As shown in the diagram on the lower portion of FIG. 1, third coil 113 is disposed at a position at which first rotation axis R1 passes through the center or approximate center of third coil 113 and second rotation axis R2 passes through the center or approximate center of third coil 113. Thus, first rotation axis R1 and second rotation axis R2 intersect each other at the center or approximate center of third coil 113.

The voice coil motor includes first to third coils 111 to 113 and magnet 30. A processor 115 that controls the voice coil motor is mounted on substrate 114. Processor 115 controls the magnitude and direction of a current to be supplied to each of first to third coils 111 to 113.

The voice coil motor and processor 115 are an exemplary driver. The driver includes a controller exemplified by processor 115 and a drive member exemplified by the voice coil motor.

In accordance with the direction of the current to be supplied to first coil 111 by processor 115, a Lorentz force is generated as shown in the lower portion of FIG. 1 so as to move magnet 30 in a direction of arrow D11A or arrow D11B when viewed in a plan view. In accordance with the direction of the current to be supplied to second coil 112 by processor 115, a Lorentz force is generated as shown in the lower portion of FIG. 1 so as to move magnet 30 in a direction of arrow D12A or arrow D12B when viewed in a plan view. In accordance with the direction of the current to be supplied to third coil 113 by processor 115, a Lorentz force is generated so as to move magnet 30 in a direction of arrow D13A or arrow D13B when viewed in a plan view.

Prism 10 is rotated together with prism holder 20 around first rotation axis R1 and second rotation axis R2 by the Lorentz forces generated by magnet 30 fixed to the bottom surface of prism holder 20 and the currents supplied to first to third coils 111 to 113.

In order to rotate prism 10 around first rotation axis R1, currents having opposite directions and the same or substantially the same absolute value should be supplied to first coil 111 and second coil 112. On the other hand, in order to rotate prism 10 around second rotation axis R2, a current should be supplied to third coil 113 and the rotation direction can be changed by changing the direction of the current.

A first rotation detection sensor 121 that detects a rotation angle of prism 10 around first rotation axis R1 is provided on substrate 114 at a center position through which first rotation axis R1 passes. A second rotation detection sensor 122 that detects a rotation angle of prism 10 around second rotation axis R2 is provided on substrate 114 at an end spaced away from the position of first rotation detection sensor 121 in parallel or substantially in parallel in the X axis direction.

Each of first rotation detection sensor 121 and second rotation detection sensor 122 is an exemplary rotation detection sensor. Each of first rotation detection sensor 121 and second rotation detection sensor 122 is defined by, for example, a tunnel magnetoresistance (TMR) element.

In the present preferred embodiment, the plurality of coils 111 to 113 are disposed on the same plane of substrate 114. Therefore, the structure of shake prevention mechanism 110 can be simplified and/or reduced in size as compared with a configuration in which coils are disposed on a plurality of planes such as the bottom surface or side surfaces of shake prevention mechanism 110.

Further, in the present preferred embodiment, the plurality of rotation detection sensors 121, 122 that detect the rotation angles of prism 10 around the two axes are also disposed on the same plane of substrate 114. Therefore, the structure of shake prevention mechanism 110 can be further simplified and/or reduced in size. In FIG. 1, the positions of second rotation detection sensor 122 and processor 115 may be replaced with each other.

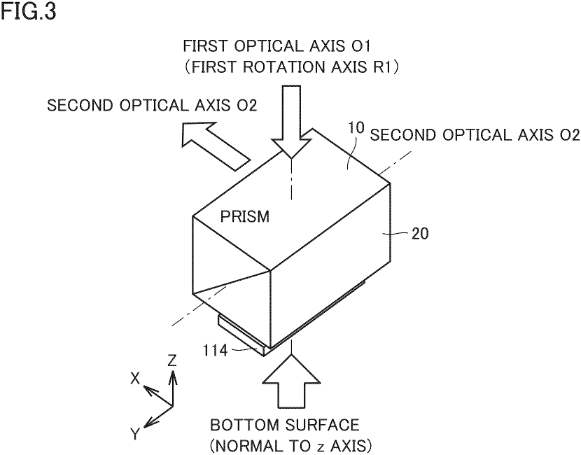

FIG. 3 is a perspective view of prism 10 for illustrating a relationship among first optical axis 01, second optical axis 02, first rotation axis R1, and second rotation axis R2. As shown in FIG. 3, the light having entered on first optical axis O1 is reflected by prism 10 and travels along second optical axis O2. Prism 10 is held to be rotatable around the two axes, i.e., first rotation axis R1 and second rotation axis R2.

Substrate 114 is disposed below prism holder 20. As described with reference to FIGS. 1 and 2, substrate 114 is provided with first coil 111, second coil 112, and third coil 113. Therefore, first to third coils 111 to 113 are located on the same plane perpendicular or substantially perpendicular to the light entrance axis of prism 10. Further, substrate 114 is also provided with first rotation detection sensor 121 and second rotation detection sensor 122. Thus, first rotation detection sensor 121 and second rotation detection sensor 122 are located on the same plane perpendicular or substantially perpendicular to the light entrance axis of prism 10.

By rotating prism 10 around first rotation axis R1, a shake with respect to the depth direction (X axis direction) toward second optical axis O2 can be corrected. By rotating prism 10 around second rotation axis R2, a shake with respect to the upward/downward direction (Z axis direction) can be corrected. Explanation for Block Diagram of Periscope Type Compact Camera Module 100

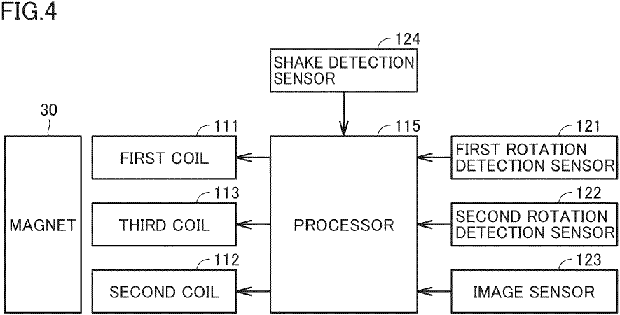

FIG. 4 is a block diagram showing the configuration of periscope type compact camera module 100. At least first to third coils 111 to 113, first rotation detection sensor 121, second rotation detection sensor 122, image sensor 123, and a shake detection sensor 124 are connected to processor 115.

Processor 115 controls the magnitude and direction of a current to be supplied to each of first to third coils 111 to 113. Processor 115 receives a detection value of first rotation detection sensor 121, a detection value of second rotation detection sensor 122, and a detection value of image sensor 123.

Processor 115 specifies the rotation angle of prism 10 around first rotation axis R1 based on the detection value of first rotation detection sensor 121 while rotating prism 10 around first rotation axis R1 by controlling the current to be supplied to each of first to third coils 111 to 113.

Processor 115 specifies the rotation angle of prism 10 around second rotation axis R2 based on the detection value of second rotation detection sensor 122 while rotating prism 10 around second rotation axis R2 by controlling the current to be supplied to each of first to third coils 111 to 113.

Periscope type compact camera module 100 is mounted as one of components of a camera on a mobile terminal such as a smartphone, for example.

When the mobile terminal with periscope type compact camera module 100 mounted thereon is shaken in downward, leftward, and rightward directions while capturing an image of a subject using the mobile terminal, a deviation occurs in the direction of the optical axis. The deviation in the direction of the optical axis is detected by shake detection sensor 124. Shake detection sensor 124 is defined by, for example, an acceleration sensor or the like. Processor 115 includes a correction calculator, and calculates a correction value for correcting the deviation of the optical axis based on the detection value of shake detection sensor 124.

This correction value is information regarding the rotation angles at which prism 10 should be rotated around first rotation axis R1 and second rotation axis R2 shown in FIGS. 1 to 3. Processor 115 controls first to third coils 111 to 113 based on the calculated correction value so as to rotate prism 10.

Processor 115 performs feedback control on an output having linearity and obtained from each of first rotation detection sensor 121 and second rotation detection sensor 122, so as to adjust the magnitude and direction of the current to be supplied to each of first to third coils 111 to 113.

By such an adjustment, processor 115 can control the rotation angle of prism 10 using the value of first rotation detection sensor 121 or the value of second rotation detection sensor 122 so as to obtain the correction value as intended. As a result, processor 115 can correct the optical axis smoothly and quickly. Thus, according to the present preferred embodiment, by rotating prism 10 when forming the image of the incoming light from the subject on image sensor 123, the light can stably enter image sensor 123 even when the camera itself is shaken.

Processor 115 and shake detection sensor 124 may be provided in the mobile terminal with periscope type compact camera module 100 mounted thereon, rather than periscope type compact camera module 100 itself.

### Control of Current Value for Rotating Prism 10

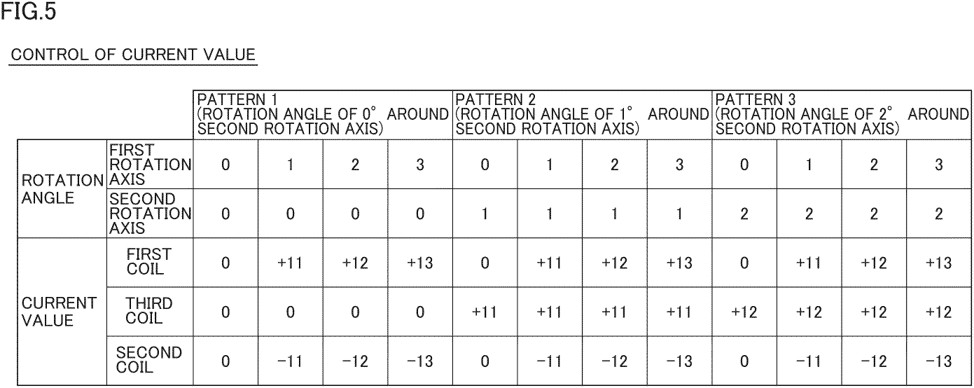

FIG. 5 is a diagram showing a relationship between a value of the current to be supplied to each of first to third coils 111 to 113 and the rotation angle of prism 10. Referring to FIG. 5, the following describes the relationship between the value of the current to be supplied to each of first to third coils 111 to 113 and the rotation angle of prism 10.

A “pattern 1” indicates values of currents to be supplied to first to third coils 111 to 113 in order to obtain, for example, a rotation angle of about 0° around second rotation axis R2 and a rotation angle of about 0° to about 3° around first rotation axis R1. A “pattern 2” indicates values of currents to be supplied to first to third coils 111 to 113 in order to obtain, for example, a rotation angle of about 1° around second rotation axis R2 and a rotation angle of about 0° to about 3° around first rotation axis R1. A “pattern 3” indicates values of currents to be supplied to first to third coils 111 to 113 in order to obtain, for example a rotation angle of about 2° around second rotation axis R2 and a rotation angle of about 0° to about 3° around first rotation axis R1.

Current values +I1, +I2, +I3, -I1, -I2, and -I3 shown in FIG. 5 are predetermined current values. These current values can be determined to be appropriate values by measuring the rotation angle of prism 10 around each of first rotation axis R1 and second rotation axis R2 while changing the values of the currents to be supplied to first to third coils 111 to 113.

### Pattern 1

The following describes pattern 1 in which the rotation angle around second rotation axis R2 is about 0°. When both the rotation angles around first rotation axis R1 and second rotation axis R2 are controlled to about 0°, no current is supplied to any of first to third coils 111 to 113.

When the rotation angle around first rotation axis R1 is controlled to about 1°, a current of +I1 is supplied to first coil 111, and a current of -I1 is supplied to second coil 112. When the rotation angle around first rotation axis R1 is controlled to about 2°, a current of +I2 is supplied to first coil 111, and a current of -I2 is supplied to second coil 112. When the rotation angle around first rotation axis R1 is controlled to about 3°, a current of +I3 is supplied to first coil 111 and a current of -I3 is supplied to second coil 112.

In other words, prism 10 can be rotated only around first rotation axis R1 by supplying first coil 111 and second coil 112 with the currents having the same or substantially the same absolute value and opposite signs.

Here, the following describes a principle thereof in detail with reference to FIG. 1. When the currents having the same or substantially the same absolute value and opposite signs are supplied to first coil 111 and second coil 112, a force in the direction of arrow D11A is exerted on magnet 30 by first coil 111, for example. On this occasion, a force in the direction of arrow D12B is exerted on magnet 30 by second coil 112.

Although arrow D11A only represents the force exerted in the X axis direction, a force is also exerted on magnet 30 in the Z axis direction. Similarly, although arrow D12B only represents the force exerted in the X axis direction, a force is also exerted on magnet 30 in the Z axis direction. The force exerted in the Z axis direction on magnet 30 by first coil 111 and the force exerted in the Z axis direction on magnet 30 by second coil 112 have the same magnitude and are exerted in opposite directions.

Therefore, the force exerted in the Z axis direction on magnet 30 by first coil 111 and the force exerted in the Z axis direction on the magnet by second coil 112 are canceled with each other. As a result, prism 10 can be rotated around second rotation axis R2 while canceling the forces in the Z axis (first rotation axis R1) direction by supplying first coil 111 and second coil 112 with the currents having the same or substantially the same absolute value and opposite directions.

Further, as the absolute value is increased, the absolute value of the rotation angle can be increased. Of course, by replacing the direction of the current to be supplied to first coil 111 with the direction of the current to be supplied to second coil 112, the rotation direction around first rotation axis R1 can be changed.

### Pattern 2

The following describes pattern 2 in which the rotation angle around second rotation axis R2 is about 1°. When the rotation angle around first rotation axis R1 is controlled to about 0° and the rotation angle around second rotation axis R2 is controlled to about 1°, a current of +I1 is supplied to third coil 113. Since no current is supplied to each of first coil 111 and second coil 112 located beside third coil 113 with third coil 113 being interposed therebetween, prism 10 is rotated only around second rotation axis R2 without rotating around first rotation axis R1.

When the rotation angle around first rotation axis R1 is controlled to about 1° or more, as with pattern 1, currents having the same absolute value and opposite signs should be supplied to first coil 111 and second coil 112. As the absolute value is increased, the rotation angle around first rotation axis R1 is increased as shown in FIG. 5.

### Pattern 3

The following describes pattern 3 in which the rotation angle around second rotation axis R2 is about 2°. When the rotation angle around first rotation axis R1 is controlled to about 0° and the rotation angle around second rotation axis R2 is controlled to about 2°, a current of +I2 is supplied to third coil 113. No current is supplied to first coil 111 and second coil 112 located beside third coil 113 with third coil 113 being interposed therebetween.

When the rotation angle around first rotation axis R1 is controlled to about 1° or more, as with pattern 2, currents having the same absolute value and opposite signs should be supplied to first coil 111 and second coil 112. As the absolute value is increased, the rotation angle around first rotation axis R1 is increased as shown in FIG. 5.

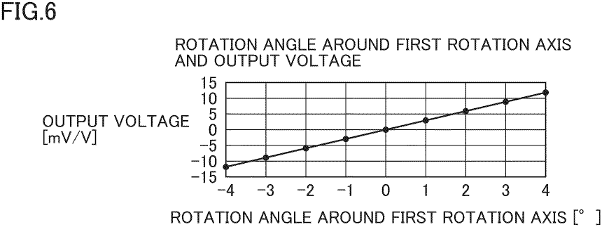

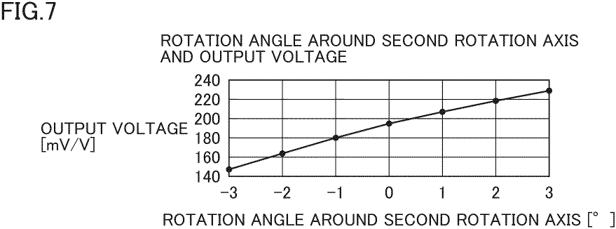

FIG. 6 is a graph showing a relationship between the rotation angle of prism 10 around first rotation axis R1 and the output voltage of first rotation detection sensor 121. FIG. 7 is a graph showing a relationship between the rotation angle of prism 10 around second rotation axis R2 and the output voltage of second rotation detection sensor 122.

When a current is supplied to each of first to third coils 111 to 113, a Lorentz force is exerted on magnet 30 attached to the bottom surface of prism holder 20. As a result, prism 10 is moved together with prism holder 20. Since the positional relationship is changed between magnet 30 and each of first rotation detection sensor 121 and second rotation detection sensor 122, a magnetic flux density in each of first rotation detection sensor 121 and second rotation detection sensor 122 is changed. The change in magnetic flux density causes a change in voltage output from each of first rotation detection sensor 121 and second rotation detection sensor 122.

As shown in FIG. 6, the rotation angle of prism 10 around first rotation axis R1 corresponds to the output voltage of first rotation detection sensor 121 in a one-to-one relationship. Similarly, as shown in FIG. 7, the rotation angle of prism 10 around second rotation axis R2 corresponds to the output voltage of second rotation detection sensor 122 in a one-to-one relationship. Therefore, when the output voltage of first rotation detection sensor 121 and the output voltage of second rotation detection sensor 122 can be specified, the rotation angles of prism 10 around first rotation axis R1 and second rotation axis R2 can be uniquely specified.

Processor 115 shown in FIG. 4 stores a table indicating the relationship between the rotation angle and the output voltage shown in FIGS. 6 and 7. Processor 115 specifies the rotation angles of prism 10 around first rotation axis R1 and second rotation axis R2 based on the stored table and the output voltages of first rotation detection sensor 121 and second rotation detection sensor 122.

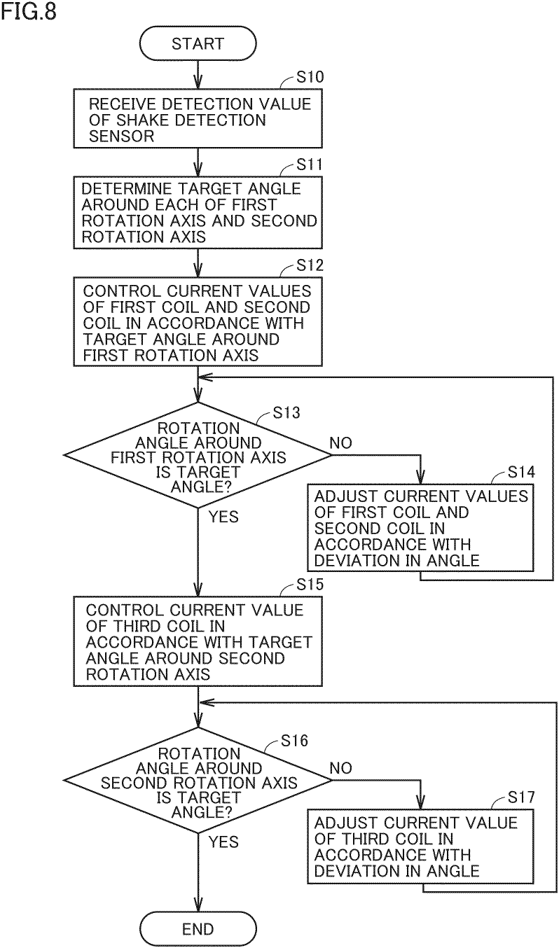

FIG. 8 is a flowchart showing a content of control for rotating prism 10 around the two axes. The process based on this flowchart is performed by processor 115 included in periscope type compact camera module 100.

First, processor 115 receives a detection value of shake detection sensor 124 (step S10). Processor 115 determines a target angle for rotating around each of first rotation axis R1 and second rotation axis R2 based on a shake angle specified from the detection value of shake detection sensor 124 (step S11).

Next, processor 115 controls the current values of first coil 111 and second coil 112 in accordance with the target angle around first rotation axis R1 (step S12). Thus, rotation is made around first rotation axis R1 by the target angle. An error may occur between the angle calculated based on the current values and the actual rotation angle. Therefore, processor 115 determines whether or not the rotation angle around first rotation axis R1 is the target angle (step S13). On this occasion, processor 115 determines whether or not the rotation angle around first rotation axis R1 is the target angle based on the detection value of first rotation detection sensor 121.

When processor 115 determines that the rotation angle around first rotation axis R1 is not the target angle, processor 115 adjusts the current values of first coil 111 and second coil 112 in accordance with the deviation in angle (step S14). Then, in step S13, processor 115 determines whether or not the rotation angle around first rotation axis R1 is the target angle.

When processor 115 determines in S13 that the rotation angle around first rotation axis R1 is the target angle, processor 115 controls the current value of third coil 113 in accordance with the target angle around second rotation axis R2 (step S15). Thus, rotation is made around second rotation axis R2 by the target angle. An error may occur between the angle calculated based on the current values and the actual rotation angle. Therefore, processor 115 determines whether or not the rotation angle around second rotation axis R2 is the target angle (step S16). On this occasion, processor 115 determines whether or not the rotation angle around second rotation axis R2 is the target angle based on the detection value of second rotation detection sensor 122.

When processor 115 determines that the rotation angle around second rotation axis R2 is not the target angle, processor 115 adjusts the current value of second coil 112 in accordance with the deviation in angle (step S17) . Then, in step S15, processor 115 determines whether or not the rotation angle around second rotation axis R2 is the target angle.

When processor 115 determines in S16 that the rotation angle around first rotation axis R1 is the target angle, processor 115 ends the process that is based on the present flowchart.

After determining in step S16 that the rotation angle around second rotation axis R2 is the target angle, processor 115 may return to the process of step S13 so as to determine whether or not the adjusted rotation angle around first rotation axis R1 is changed from the target angle.

According to the first preferred embodiment described above, first to third coils 111 to 113 for rotating prism 10 are disposed on the same plane of substrate 114. Therefore, the structure of shake prevention mechanism 110 can be simplified and/or reduced in size as compared with a configuration in which coils are disposed on a plurality of planes such as the bottom surface or side surfaces of shake prevention mechanism 110.

In particular, since first to third coils 111 to 113 are flush with one another on the plane below prism 10, the thickness of shake prevention mechanism 110 in the Z axis direction can be reduced or prevented. Further, since first to third coils 111 to 113 are collectively disposed on the plane below prism 10, no coil needs to be provided on a side surface of shake prevention mechanism 110. Therefore, the thickness of shake prevention mechanism 110 in the X axis direction or the Y axis direction can also be reduced or prevented.

Further, in the present preferred embodiment, the plurality of rotation detection sensors 121 and 122 are also disposed on the same plane of substrate 114. Therefore, the structure of shake prevention mechanism 110 can be further simplified and/or reduced in size.

### Second Preferred Embodiment

In the first preferred embodiment, it has been illustratively described that prism 10 is rotated around the two axes by the three coils, i.e., first to third coils 111 to 113 provided on substrate 114. In a second preferred embodiment of the present invention, it will be illustratively described that prism 10 is rotated around the two axes by two coils provided on substrate 114.

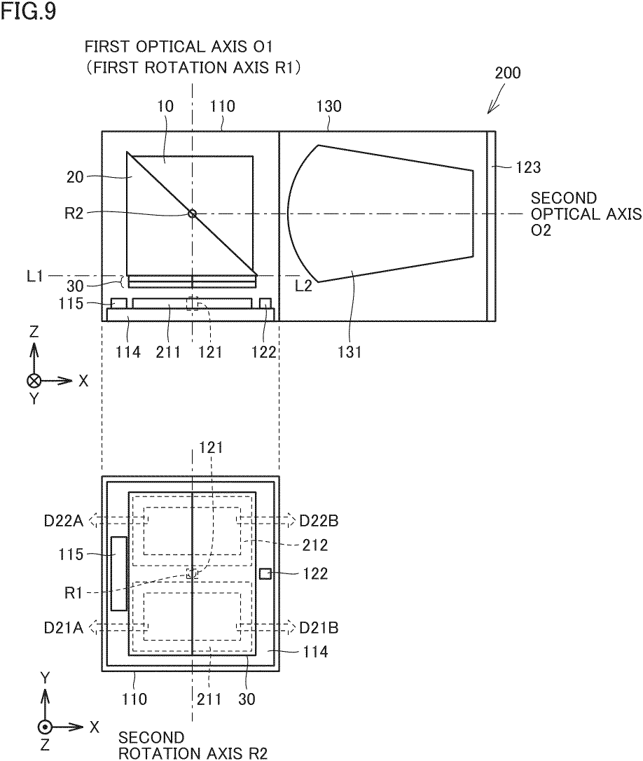

FIG. 9 is a transparent plan view of a periscope type compact camera module 200 according to the second preferred embodiment. In particular, the upper portion of FIG. 9 shows a diagram of periscope type compact camera module 200 when viewed in the Y axis direction. As compared with the block diagram shown in FIG. 4, a circuit configuration of periscope type compact camera module 200 is the same or substantially the same as the circuit configuration of periscope type compact camera module 100, except that the number of coils is two.

In periscope type compact camera module 200 according to the second preferred embodiment, two coils, i.e., a first coil 211 and a second coil 212 are provided on substrate 114. First rotation detection sensor 121 that detects the rotation angle of prism 10 around first rotation axis R1 is provided at the center position thereof through which first rotation axis R1 passes. Second rotation detection sensor 122 that detects the rotation angle of prism 10 around second rotation axis R2 is provided on substrate 114 at an end spaced way from the position of first rotation detection sensor 121 in parallel or substantially in parallel in the X axis direction.

In the second preferred embodiment, as with the first preferred embodiment, the plurality of coils 211 and 212 are disposed on the same plane of substrate 114. Therefore, the structure of shake prevention mechanism 110 can be simplified and/or reduced in size as compared with a configuration in which coils are disposed on a plurality of planes such as the bottom surface or side surfaces of shake prevention mechanism 110.

Further, in the second preferred embodiment, the plurality of rotation detection sensors 121 and 122 that detect the rotation angles of prism 10 around the two axes are also disposed on the same plane of substrate 114. Therefore, the structure of shake prevention mechanism 110 can be further simplified and/or reduced in size. In FIG. 9, the positions of second rotation detection sensor 122 and processor 115 may be replaced with each other.

In accordance with the direction of the current to be supplied to first coil 211 by processor 115, a Lorentz force is generated as shown in the lower portion of FIG. 9 so as to move magnet 30 in a direction of arrow D21A or arrow D21B when viewed in a plan view. In accordance with the direction of the current to be supplied to second coil 212 by processor 115, a Lorentz force is generated as shown in the lower portion of FIG. 9 so as to move magnet 30 in a direction of arrow D22A or arrow D22B when viewed in a plan view.

Prism 10 is rotated around the two axes by the Lorentz forces generated by magnet 30 fixed to the bottom surface of prism holder 20 and the currents supplied to first coil 211 and second coil 212.

In order to rotate prism 10 around first rotation axis R1, currents having opposite directions and the same or substantially the same absolute value should be supplied to first coil 211 and second coil 212. On the other hand, in order to rotate prism 10 around second rotation axis R2, currents having the same direction and the same or substantially the same absolute value should be supplied to first coil 211 and second coil 212.

Prism 10 can be rotated around first rotation axis R1 and second rotation axis R2 by variously adjusting the magnitude and direction of the current to be supplied to first coil 211 and the magnitude and direction of the current to be supplied to second coil 212. Processor 115 performs feedback control on an output having linearity and obtained from each of first rotation detection sensor 121 and second rotation detection sensor 122, so as to adjust the magnitude and direction of the current to be supplied to each of first coil 211 and second coil 212.

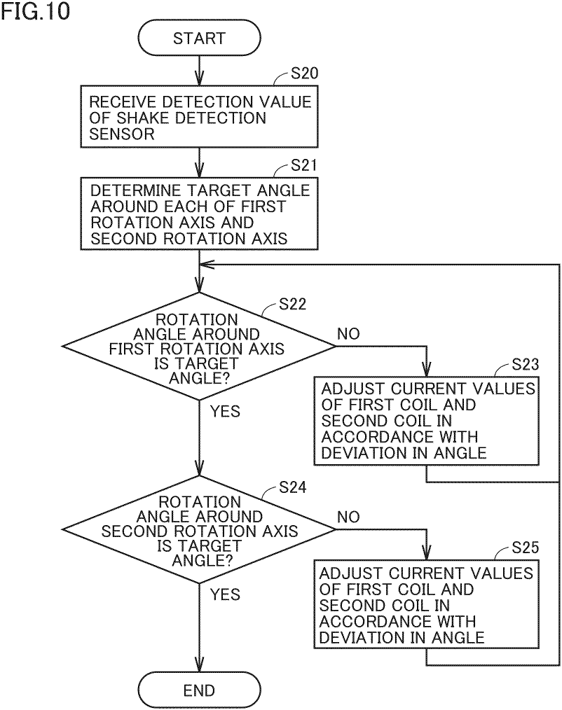

FIG. 10 is a flowchart showing a content of control for rotating prism 10 around the two axes. The process based on this flowchart is performed by processor 115 included in periscope type compact camera module 200.

First, processor 115 receives a detection value of shake detection sensor 124 (step S20). Processor 115 determines a target angle for rotating around each of first rotation axis R1 and second rotation axis R2 based on a shake angle specified from the detection value of shake detection sensor 124 (step S21).

Next, processor 115 determines whether or not the rotation angle around first rotation axis R1 is a target angle (step S22). Processor 115 determines whether or not the rotation angle around first rotation axis R1 reaches the target angle based on the detection value of first rotation detection sensor 121.

When processor 115 determines that the rotation angle around first rotation axis R1 is not the target angle, processor 115 adjusts the current values of first coil 211 and second coil 212 in accordance with the deviation in angle (step S23). Then, the current values of first coil 211 and second coil 212 are adjusted in accordance with the deviation in angle until the rotation angle around first rotation axis R1 reaches the target angle.

When processor 115 determines in step S22 that the rotation angle around first rotation axis R1 is the target angle, processor 115 determines whether or not the rotation angle around second rotation axis R2 reaches the target angle based on the detection value of second rotation detection sensor 122 (step S24).

When processor 115 determines that the rotation angle around second rotation axis R2 is not the target angle, processor 115 adjusts the current values of first coil 211 and second coil 212 in accordance with the deviation in angle (step S25). Then, processor 115 returns to the process of step S22 and determines again whether or not the rotation angle around first rotation axis R1 is the target angle. A reason why the process is returned from step S25 to step S22 in this way is because the adjustment of the rotation angle around second rotation axis R2 may affect the rotation angle around first rotation axis R1.

Processor 115 repeats the processes of steps S22 to S25 described above, and ends the process that is based on the present flowchart in a stage in which it is determined that both the rotation angle around first rotation axis R1 and the rotation angle around second rotation axis R2 reach the target angles (YES in step S24).

Processor 115 may store in advance data indicating the relationship between the current to be supplied to each of first coil 211 and second coil 212 and the rotation angle around each of first rotation axis R1 and second rotation axis R2. In this case, processor 115 can control the rotation angle around each of first rotation axis R1 and second rotation axis R2 based on the stored data. When there is a deviation between the rotation angle and the target angle, processor 115 may adjust the value of the current to be supplied to each of first coil 211 and second coil 212, based on steps S23 and S25.

### Modifications

Hereinafter, modifications and features of the above-described preferred embodiments will be further described.

The tunnel magnetoresistance (TMR) element has been described as an example of each of rotation detection sensors 121 and 122. However, the rotation detection sensor is not limited thereto, and a different type of magnetoresistance sensor may be used.

For example, a giant magnetoresistance (GMR) element or an anisotropic magnetoresistance (AMR) element may be used as the magnetoresistance sensor. Alternatively, each of rotation detection sensors 121 and 122 may be provided by combining these magnetoresistance elements.

For example, it is conceivable that first rotation detection sensor 121 includes a TMR element and second rotation detection sensor 122 includes a GMR element. Alternatively, it is conceivable that first rotation detection sensor 121 includes an AMR element and the second rotation detection sensor includes a GMR element.

In each of the first and second preferred embodiments, prism 10 has been illustratively described as the example of the refractor. However, for example, a mirror may be used instead of prism 10.

The position of first rotation detection sensor 121 may be deviated to the left or right in the X axis direction from the position through which first rotation axis R1 passes. Conversely, the position of first rotation axis R1 may be deviated to the left or right in the X axis direction.

First rotation axis R1 is an axis along first optical axis O1 and coincides with first optical axis O1. Second rotation axis R2 is an axis perpendicular or substantially perpendicular to the imaginary plane formed by first optical axis O1 and second optical axis O2 and orthogonal or substantially orthogonal to first optical axis O1. However, first rotation axis R1 may be any axis as long as it is parallel or substantially parallel to first optical axis O1. Also, second rotation axis R2 may be any axis as long as it is perpendicular or substantially perpendicular to the imaginary plane formed by first optical axis O1 and second optical axis O2.

For example, first rotation axis R1 may be an axis obtained by deviating first optical axis O1 by a predetermined distance in the direction of second optical axis O2. Specifically, in the diagram on the upper portion of FIG. 1, first rotation axis R1 may represent an axis obtained by deviating first optical axis O1 in the X axis direction. Further, in the diagram on the upper portion of FIG. 1, second rotation axis R2 may represent an axis obtained by deviating, in the Z axis direction, the axis being orthogonal or substantially orthogonal to first optical axis O1 and second optical axis O2. Each of a distance by which first optical axis O1 is deviated in the X axis direction and a distance by which the axis orthogonal or substantially orthogonal to first optical axis O1 and second optical axis O2 is deviated in the Z axis direction may be appropriately designed in accordance with the sizes of prism 10, prism holder 20, magnet 30, and the like.

Processor 115 may be provided at a location other than shake prevention mechanism 110. For example, when each of periscope type compact camera modules 100, 200 is provided in a mobile terminal, a processor provided on the mobile terminal side may define and function as processor 115.

Magnet 30 may include a plurality of magnets divided in the Y axis direction. For example, three magnets may be provided on the bottom surface of prism holder 20 so as to respectively correspond to first to third coils 111 to 113. However, it is preferable to provide magnet 30 without dividing magnet 30 in such a manner. This is due to the following reason. The direction of magnetic flux density at each of the positions of first rotation detection sensor 121 and second rotation detection sensor 122 is stable even when prism 10 is rotated.

As a configuration of prism holder 20 to hold prism 10 to be rotatable around the two axes, various configurations are conceivable, such as utilization of a repulsive force of magnets. For example, in the configuration of prism holder 20 shown on the left side of FIG. 2, a curved surface may be provided so as to bulge at a certain curvature from each of the both side surfaces of prism holder 20 to a portion of the bottom surface of prism holder 20, a holder may be provided at each of the both side surfaces of shake prevention mechanism 110 and a portion of the bottom surface of shake prevention mechanism 110 so as to hold the curved surface with a curvature corresponding to the curved surface. By providing the curved surface and the holder in this manner, prism holder 20 can be rotated around two axes.

Alternatively, in the diagram on the left side of FIG. 2, shafts may be provided on both of the side surfaces of prism holder 20 in the Y axis direction so as to support prism holder 20 in the direction of second rotation axis R2, and the left shaft may support it on the left side surface of shake prevention mechanism 110, and the right shaft may support it on the right side surface of shake prevention mechanism 110. Thus, prism holder 20 can be rotated around second rotation axis R2. Further, in the configuration of prism holder 20 shown on the left side in FIG. 2, prism holder 20 may be rotatable around first rotation axis R1 by providing a shaft that supports the bottom surface of prism holder 20 and the bottom surface of shake prevention mechanism 110 so as to be rotatable around first rotation axis R1.

In the first preferred embodiment, the number of the coils included in the driver is three. In the second preferred embodiment, the number of the coils included in the driving section is two. In each of the preferred embodiments, the plurality of coils are disposed on the same plane. The driver may include four or more coils. Also when the driver includes four or more coils, processor 115 can rotate prism 10 to a desired rotation angle around two axes by controlling value and direction of current to be supplied to each of the coils.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A shake correction mechanism comprising:
a refractor to refract, in a direction of a second optical axis of an optical element system, incoming light that entered along a first optical axis;
a holder to hold the refractor; and
a driver to rotate the refractor together with the holder around a first rotation axis and a second rotation axis, the first rotation axis being parallel or substantially parallel to the first optical axis, the second rotation axis being perpendicular or substantially perpendicular to an imaginary plane defined by the first optical axis and the second optical axis; wherein
the driver includes a magnet and a plurality of coils;
the magnet is provided on the holder at a position opposite to a side on which the incoming light enters the refractor in a direction of the first optical axis; and
the plurality of coils face the holder with the magnet being interposed between each of the plurality of coils and the holder, and are provided on a same or substantially a same plane perpendicular or substantially perpendicular to the first optical axis.

2. The shake correction mechanism according to claim 1, further comprising:
a first rotation detection sensor to detect the rotation of the refractor around the first rotation axis; and
a second rotation detection sensor to detect the rotation of the refractor around the second rotation axis; wherein
the first rotation detection sensor and the second rotation detection sensor are provided on the plane on which the plurality of coils are provided.

3. The shake correction mechanism according to claim 2, wherein the driver is operable to adjust a rotation angle of the refractor around the first rotation axis and a rotation angle of the refractor around the second rotation axis based on an output value of the first rotation detection sensor and an output value of the second rotation detection sensor.

4. The shake correction mechanism according to claim 2, wherein the first rotation detection sensor or the second rotation detection sensor includes an anisotropic magnetoresistance element.

5. The shake correction mechanism according to claim 2, wherein the first rotation detection sensor or the second rotation detection sensor includes a giant magnetoresistance element.

6. The shake correction mechanism according to claim 2, wherein the first rotation detection sensor or the second rotation detection sensor includes a tunnel magnetoresistance element.

7. The shake correction mechanism according to claim 1, wherein the plurality of coils are side by side in a direction orthogonal or substantially orthogonal to a direction passing through an N pole and an S pole of the magnet.

8. The shake correction mechanism according to claim 1, wherein
the plurality of coils include a first coil and a second coil; and
the driver is operable to rotate the refractor around the first rotation axis by supplying the first coil and the second coil with currents in opposite directions.

9. The shake correction mechanism according to claim 8, wherein the plurality of coils further include a third coil between the first coil and the second coil.

10. The shake correction mechanism according to claim 9, wherein the driver is operable to rotate the refractor around the second rotation axis by controlling a magnitude and a direction of a current to be supplied to the third coil.

11. A camera module comprising the shake correction mechanism according to claim 1.

12. The camera module according to claim 11, further comprising:
a first rotation detection sensor to detect the rotation of the refractor around the first rotation axis; and
a second rotation detection sensor to detect the rotation of the refractor around the second rotation axis; wherein
the first rotation detection sensor and the second rotation detection sensor are provided on the plane on which the plurality of coils are provided.

13. The camera module according to claim 12, wherein the driver is operable to adjust a rotation angle of the refractor around the first rotation axis and a rotation angle of the refractor around the second rotation axis based on an output value of the first rotation detection sensor and an output value of the second rotation detection sensor.

14. The camera module according to claim 12, wherein the first rotation detection sensor or the second rotation detection sensor includes an anisotropic magnetoresistance element.

15. The camera module according to claim 12, wherein the first rotation detection sensor or the second rotation detection sensor includes a giant magnetoresistance element.

16. The camera module according to claim 12, wherein the first rotation detection sensor or the second rotation detection sensor includes a tunnel magnetoresistance element.

17. The camera module according to claim 11, wherein the plurality of coils are side by side in a direction orthogonal or substantially orthogonal to a direction passing through an N pole and an S pole of the magnet.

18. The camera module according to claim 11, wherein
the plurality of coils include a first coil and a second coil; and
the driver is operable to rotate the refractor around the first rotation axis by supplying the first coil and the second coil with currents in opposite directions.

19. The camera module according to claim 18, wherein the plurality of coils further include a third coil between the first coil and the second coil.

20. The camera module according to claim 19, wherein the driver is operable to rotate the refractor around the second rotation axis by controlling a magnitude and a direction of a current to be supplied to the third coil.
